(19) United States
(12) Patent Application Publication
(10) Pub. No.: US 2021/0110292 A1
(43) Pub. Date: Apr. 15, 2021

(54) Method for learning from a compression/decompression context and corresponding device, system and computer program product

(71) Applicant: ACKLIO, Cesson Sévigné (FR)

(72) Inventors: Ana MINABURO, CESSON SEVIGNE (FR); Alexander PELOV, RENNES (FR)

(73) Assignee: ACKLIO, Cesson Sévigné (FR)

(21) Appl. No.: 16/497,481

(22) PCT Filed: Mar. 29, 2018
(86) PCT No.: PCT/EP2018/058086

§ 371 Date: Sep. 25, 2019

(30) Foreign Application Priority Data
Mar. 29, 2017 (FR) 1752627

(51) Int. Cl. G06N 20/00; H03M 7/30; H04W 84/04; H04L 12/28; H04L 29/06

(52) U.S. Cl. CPC G06N 20/00; H03M 7/30; H04L 69/04; H04L 12/2854; H04W 84/042

(57) ABSTRACT

The invention relates to a method for learning a compression/decompression context comprising at least one compression/decompression rule intended to be used by a compressor device and a decompressor device to compress and decompress a first data stream transmitted via at least one first communication link, respectively. In such a method at least one device, among the compressor device, the decompressor device and a third device, carries out the following steps:
analyzing (E200) at least one second non-compressed data stream transmitted between the compressor device and the decompressor device via at least one second communication link; and
learning (E210) the at least one compression/decompression rule depending on said analysis.

### TECHNICAL FIELD

The present invention relates to the field of compression and decompression of data (particularly, but not exclusively header data) exchanged via a communication link.

More precisely, the present invention relates to a method allowing a compression/decompression context (comprising at least one compression/decompression rule) used by two devices, one a compressor and the other a decompressor, exchanging compressed data via such a link, to be learnt while minimizing the decrease in the useful bandwidth of the link in question.

The invention has many applications, in particular, but not exclusively, in the field of the Internet of things (IoT), networks dedicated to the exchange of data for things often having a narrow bandwidth in order to limit the power consumption of these things in mobile applications.

Examples of these networks are networks based on SemTech LoRa, SIGFOX, NB-IoT, EC-GSM, Cat-M1, Weightless, Ingenu/RPMA or WI-SUN technology, or any other technology that possesses similar characteristics.

The invention may also be applied to things that communicate via shorter range networks, such as Bluetooth, Bluetooth LE, IEEE 802.15.4 and ZigBee networks.

More generally, the invention is applicable to any network the communication bandwidth of which is constrained, or that is required to connect things (even if the bandwidth of this network is not limited).

### TECHNOLOGICAL BACKGROUND

Presented as the “third digital revolution”, connected things are in the process of becoming standard in every facet of every-day and working life. Most of these things are intended to produce data by virtue of sensors incorporated therein, in order to deliver value-added services to their owner.

Because of the targeted applications, these connected things are for the most part mobile. In particular, they must be able to transmit the produced data, regularly or on request, to a remote user.

In an industrial environment such connected things allow meter values to be read, actuators to be triggered or serve as control plane for other data networks.

The mobile aspect of these things is often accompanied by a need for them to supply their own power. However, even based on one of the cellular mobile radio technologies of lowest power consumption, present-day connected things continue to have a power consumption that prevents large-scale deployment at a reasonable cost.

In response to the problem of the power consumption of the radio link in such mobile applications, new low-consumption and narrow-bandwidth radio technologies specifically dedicated to IoT networks, i.e. radio technologies for so-called LPWAN networks (low-power wide-area networks), are in the process of being developed.

More particularly, these technologies may be categorized into two groups:
on the one hand, proprietary technologies such as for example the technology of the company Sigfox®, or indeed the technology LoRa®, or even the technology of the company Qowisio®. In practice, these non-standardized technologies are all based on the use of “industrial, scientific and medical” frequency bands (i.e. what are called ISM frequency bands) and on the regulation associated with the use thereof. The advantage of these technologies is that they are already available and allow networks to be rapidly deployed with a limited investment. Furthermore, they allow connected things that have a very low power consumption to be developed at low cost;
on the other hand, several technologies promulgated by standards organizations. By way of example, mention may be made of three technologies in the process of being standardized by the 3GPP (for 3rd Generation Partnership Project): NB-IoT (for Narrow Band—Internet of Things), LTE MTC (for Long Term Evolution—Machine Type Communication) and EC-GPRS (for Extended Coverage—General Packet Radio Service). However, such solutions will be based on licensed frequency bands and moreover their specifications are not yet entirely set.

However, the common point of all these technologies is that they have a narrow bandwidth in order to decrease the power consumption of connected objects using this type of radio link to exchange their data.

In order to optimize the use of the bandwidth of an LPWAN radio link of this type, various data-compression techniques are being developed.

By way of example, the so-called SCHC technique (SCHC standing for Static Context Header Compression) is in the process of being developed by the IETF (IETF standing for Internet Engineering Task Force). Such a technique is for example described in the document by L. Toutain et al. “LPWAN Static Context Header Compression (SCHC) and fragmentation for IPv6 and UDP” (https://datatracker.ietf.org/doc/html/draft-ietf-Ipwan-ipv6-static-context-hc-02).

Specifically, most LPWAN networks use data frames (also sometimes called “packets”) that have useful portions of small size with respect to the size of the corresponding headers. Moreover, the computations carried out by most connected things must remain simple in order to limit their power consumption. Thus, the SCHC technique proposes to compress/decompress the headers used by such networks via the use of contexts comprising a set of compression/decompression rules known both to the emitter (or more precisely to the compressor device) and to the receiver (or more precisely to the decompressor device). In terms of computational load, such rules remain simple to apply by associating particular values with the header fields in question.

More particularly, the emitter simultaneously sends the compressed header data and the identifier of the rule used to compress the sent data. The compression/decompression rules being known by the receiver, the latter carries out the decompression of the received compressed data on the basis of the compression/decompression rule identified by the received identifier.

However, such a technique requires the rules to be known at both ends of the communication link, i.e. both by the emitter and by the receiver of the compressed data.

To this end, in certain cases the rules in question are defined beforehand within each device using them. In other cases, an initialization phase is implemented in which the rules in question are transmitted from one of the devices using them to the other, in order to ensure that the two devices use the same rules during their exchanges of compressed data via their emitting and receiving components.

Such an initialization phase is however problematic because it correspondingly decreases the available bandwidth of the communication link, in particular when the latter is of LPWAN type, i.e. of narrow bandwidth in practice.

Moreover, certain applications may cause the data streams to be exchanged over the communication link between the two devices to have characteristics (for example a label characterizing the conveyed stream, a port number of a source application, etc.) that are dynamic. Hence, it may prove to be beneficial to re-parameterize the compression/decompression rules in order to optimize the compression of the headers of the data frames exchanged over the communication link depending on the characteristics of the latter.

However, an update of the compression/decompression rules again requires additional data to be exchanged, thereby decreasing the bandwidth available for useful data.

Moreover, this additional exchange of data may take a long time because of the limited bandwidth of LPWAN networks, this limiting the adaptability of the compression/decompression rules to the actual data stream over the communication link. Likewise, this time taken to exchange additional data may significantly impact the real-time exchange of useful data between the devices implementing the rules in question.

There is therefore a need to initialize and/or update the compression/decompression rules implemented in the exchange of compressed data via a communication link while minimizing the decrease in the bandwidth available for useful data of the link in question.

There is also a need for such an update to occur reactively, while minimizing the real-time impact on the exchange of data over the communication link in question.

### SUMMARY

In one embodiment of the described techniques, a method is proposed for learning a compression/decompression context comprising at least one compression/decompression rule intended to be used by a compressor device and a decompressor device to compress and decompress at least one first data stream transmitted via at least one first communication link, respectively. In such a method, at least one device, among the compressor device, the decompressor device and a third device, carries out the following steps:
analyzing at least one second non-compressed data stream transmitted between the compressor device and the decompressor device via at least one second communication link (110b); and
learning said at least one compression/decompression rule depending on said analysis;

the learning step comprises modifying at least one basic compression/decompression rule, in order to obtain said at least one compression/decompression rule comprised in said compression/decompression context, said at least one basic compression/decompression rule comprises at least one adaptation-field description defining a compression/decompression behavior for an adaptation field of said at least one first data stream, and said modification comprises, for each selected basic compression/decompression rule:
for each adaptation-field description, modifying at least one attribute of said adaptation-field description, depending on a current value of said adaptation field in a packet of said at least one second data stream.

Thus, the invention proposes a novel and inventive solution for learning (i.e. initializing and/or updating) a compression/decompression context comprising compression/decompression rules implemented by a compressor device and by a decompressor device (each of the compressor and decompressor devices possibly being a device in its own right or indeed being integrated into another piece of equipment, such as for example a connected thing, a user terminal such as a smart phone or tablet, a network gateway or a core network, a server or a computer, etc.).

To this end, the described technique proposes to use a second communication link in order to allow the compression/decompression rules in question to be learnt before they are used to exchange a first data stream via the first communication link.

Thus, the bandwidth of the first communication link remains dedicated to the exchange of useful data.

Moreover, the ability to learn the compression/decompression rules without affecting the transmission rate over the first communication link makes it possible to envision updating the rules in question more frequently. Thus, adaptation of the rules to the dynamic re-parameterization of the exchange of data over the first communication link becomes envisionable.

Lastly, when the second communication link has a broader bandwidth than that of the first communication link, the length of time taken to learn the compression context is decreased.

The learning is carried out selectively on particular compression/decompression rules (selected rules) among all of the basic rules capable of being implemented by the compressor and decompressor devices.

The one or more attributes of the compression/decompression rule that it is desired for the compressor device and/or the decompressor device and/or the third device to learn are updated flexibly via information delivered over the second communication link.

The one or more attributes of the compression/decompression rule that it is desired for the compressor device and/or the decompressor device and/or the third device to learn are for example updated on the basis of predefined attribute values chosen selectively depending on the current value (in the second stream) of the adaptation field with which the attributes in question are associated.

According to one embodiment, said at least one adaptation field is a header field of a packet of the at least one first data stream, the header field conveying dynamic information of a communication protocol.

Thus, the attributes, of compression/decompression rules, that are associated with header fields conveying a dynamic parameter, i.e. a parameter not known before the establishment of the communication over the first communication link, are learned.

Such an approach to learning allows the compression and decompression rules to be adapted to changes in dynamic parameters of the communication between the compressor and decompressor devices.

According to one embodiment, said at least one attribute of the at least one adaptation-field description belongs to the group comprising:
a target value of said adaptation field;
a comparison operator enabling comparison between said target value and a current value of said adaptation field in a packet of said at least one first data stream, with a view to delivering a decision to apply a compression or decompression function to said current value; and
said compression or decompression function.

Thus, in an operating phase (subsequent to the learning phase defined by the present method), the application of the compression/decompression rule resulting from the learning phase to the actual value of a field of the data (e.g. a header field), in order to deliver a compressed or decompressed data field, is dependent on the comparison between the actual value in question and a target value associated with the data field in question by the compression/decompression rule obtained after the learning phase.

Such a compression or decompression is then carried out via the compression or decompression function associated with the data field in question by the compression/decompression rule obtained after the learning phase.

According to one embodiment, the learning step comprises selecting, depending on the at least one second non-compressed data stream, said at least one basic compression/decompression rule among a plurality of basic compression/decompression rules.

Thus, the learning is carried out selectively on particular compression/decompression rules among basic rules (e.g. templates) previously implemented in the one or more devices that implement the learning method.

According to one embodiment, each of the basic compression/decompression rules comprises at least one reference-field description defining a compression/decompression behavior and a target value for a reference field of said at least one first data stream. Said selection comprises, for each of the basic compression/decompression rules:
for each reference-field description defining a given target value for a given reference field, comparing a current value of said given reference field in a packet of said at least one second data stream, and said given target value; and
deciding to select or not select said basic compression/decompression rule depending on said comparison for each reference-field description.

Thus, a compression/decompression rule that it is desired for the compressor device and/or the decompressor device and/or the third device to learn is identified simply and robustly via a comparison carried out between the target value and the current value of a reference field of the data, to which field the rule must be applied in order to carry out the compression or decompression.

According to one embodiment, said at least one reference field is another header field of a packet of the at least one first data stream, said other header field conveying static information of the aforementioned communication protocol.

Thus, the compression/decompression rule that it is desired for the compressor device and/or the decompressor device and/or the third device to learn is identified via recognition of the value of a header field conveying a static parameter allowing the final recipient of the compressed data exchanged in the first data stream via the first communication link to be identified (e.g. the decompressor, a device into which the decompressor is integrated, or more particularly a final application for which the data are intended after decompression by the decompressor).

Thus, the described method allows a compression/decompression rule used specifically for the exchange of compressed data with one particular recipient device to be learnt.

Furthermore, the rule that it is desired to learn is identified robustly using a predefined criterion (i.e. using a criterion known before the establishment of the communication via the first communication link).

According to one embodiment, said at least one compression rule, comprised in said compression/decompression context, is in SCHC format (SCHC standing for Static Context Header Compression).

According to another embodiment, said at least one first communication link is a link of a low-power wide-area network (LPWAN).

For example, it is a question of one of the following types of network: LoRa®, SIGFOX®, NB-IoT (for Narrow Band—Internet of Things), EC-GPRS (for Extended Coverage—General Packet Radio Service), LTE (for Long Term Evolution) cat-M1, Weightless®, Ingenu/RPMA®, WI-SUN, etc.

According to yet another embodiment, said at least one second communication link is a link of a cellular wireless network.

For example, it is a 2G/3G/4G cellular radio link, etc.

According to one embodiment, the decompressor device and the decompressor device each carry out the analyzing and learning steps.

Thus, the overall implementation of such an approach to learning is simplified.

According to another embodiment, one of the compressor and decompressor devices carries out the analyzing and learning steps, and in that the other of the compressor and decompressor devices receives the compression/decompression context resulting from said analyzing and learning steps.

According to yet another embodiment, the third device carries out the analyzing and learning steps, and in that the compressor device and the decompressor device each receive the compression/decompression context resulting from said analyzing and learning steps.

The invention also relates to a computer program, comprising program-code instructions for implementing a method for learning a compression/decompression context, according to any one of its various embodiments, when said program is executed on a computer.

In another embodiment of the invention, a device is proposed for learning a compression/decompression context comprising at least one compression/decompression rule intended to be used by a compressor device and a decompressor device to compress and decompress at least one first data stream transmitted via at least one first communication link, respectively. Such a device comprises a reprogrammable computational machine or a dedicated computational machine able and configured to:
analyze at least one second non-compressed data stream transmitted between the compressor device and the decompressor device via at least one second communication link; and
learn said at least one compression/decompression rule depending on said analysis;

said learning comprising modifying at least one basic compression/decompression rule, in order to obtain said at least one compression/decompression rule comprised in said compression/decompression context, said at least one basic compression/decompression rule comprising at least one adaptation-field description defining a compression/decompression behavior for an adaptation field of said at least one first data stream, said modification comprising, for each selected basic compression/decompression rule: for each adaptation-field description, modifying at least one attribute of said adaptation-field description, depending on a current value of said adaptation field in a packet of said at least one second data stream.

Such a device for learning a compression/decompression context is in particular able to implement the method for learning a compression/decompression context according to the described technique (according to any one of the various aforementioned embodiments).

Thus, the features and advantages of this device are the same as those of the learning method described above. Therefore, they are not detailed more amply.

### LIST OF THE FIGURES

Other features and advantages will become more clearly apparent on reading the following description of particular embodiments of the disclosure, which embodiments are given by way of simple illustrative and non-limiting examples, and the appended drawings, in which:

FIG. 1 illustrates a system comprising a compressor and a decompressor according to one embodiment of the described technique;

FIG. 2 illustrates the steps of a method for learning a compression/decompression context according to one embodiment of the described technique; and

FIG. 3 shows an example of a structure of a learning device allowing the method of FIG. 2 to be implemented.

### DETAILED DESCRIPTION

In all the figures of the present document, elements and steps that are identical have been referenced with the same reference.

The general principle of the described technique consists of a method for learning a compression/decompression context comprising at least one compression/decompression rule intended to be used by a compressor device and a decompressor device to compress and decompress a first data stream transmitted via a first communication link, respectively. In such a method, at least one device, among the compressor device, the decompressor device and a third device (different from the compressor device and the decompressor device) learns the compression/decompression rule in question depending on a second non-compressed data stream transmitted between the compressor device and the decompressor device via a second communication link.

Thus, the bandwidth of the first communication link remains dedicated to the exchange of useful data.

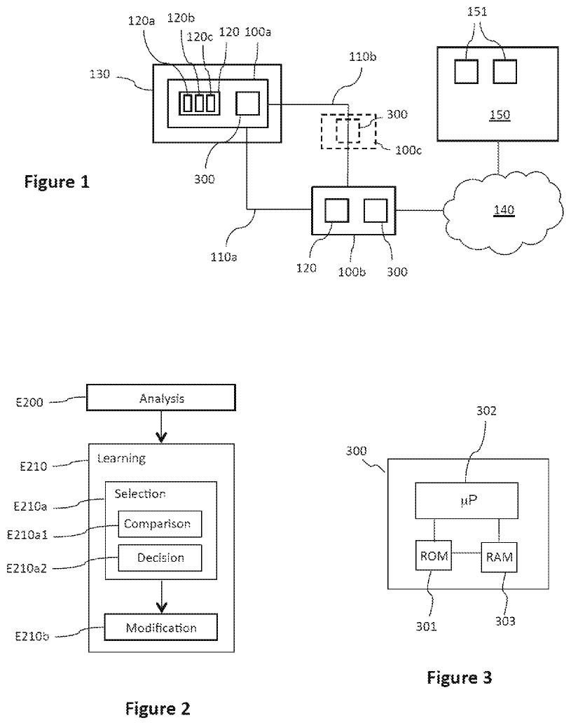

A system comprising a compressor device 100a and a decompressor device 100b according to one embodiment of the described technique will now be described with reference to FIG. 1.

In this embodiment, the compressor device 100a and the decompressor device 100b compress and decompress a first data stream transmitted via a first communication link 110a, respectively.

The first communication link 110a is a LPWAN (for example a radio link according to one of the following standards: LoRa®, SIGFOX®, NB-IoT, EC-GPRS, LTE cat-M1, Weightless®, Ingenu/RPMA®, WI-SUN, etc.).

The compressor device 100a is integrated into a connected thing 130 (for example a sensor/actuator) and the decompressor device 100b is on the path of the data between a network gateway of the LPWAN network and a core communication network (for example an IP network such as the Internet 140 or an intranet).

The data decompressed by the decompressor device 100b are thus routed to an application server 150 via the Internet 140.

More particularly, the data decompressed by the decompressor device 100b are routed to one or more target applications 151 to which the data in question, initially sent by the connected thing 130 in a form compressed by the action of the compressor device 100a, are intended.

In certain embodiments (not shown) the compressor device 100a and the decompressor device 100b compress and decompress a plurality of first data streams transmitted via one or more first communication links 110a, respectively.

In other embodiments (not shown) each of the compressor and decompressor devices 100a, 100b is a device in its own right or indeed is integrated into another piece of equipment, such as for example a connected thing, a user terminal such as a smart phone or a tablet, a network gateway or a core network, a server or a computer, a piece of cloud-computing equipment, etc.

In yet other embodiments (not shown) the other pieces of equipment in question each incorporate both a compressor device 110a and a decompressor device 110b. In these configurations, the one or more first data streams transmitted via the one or more first communication links 110a are bidirectional. Likewise, the second data stream is transmitted between a compressor device 110a and a decompressor device 110b of each of the other pieces of equipment in question.

In certain embodiments, the first communication link 110a is a short-range radio link of the Wi-Fi®, Bluetooth®, IEEE 802.15.4 or ZigBee type, or even a cellular (for example 2G/3G/4G, etc.) link, etc.

In order to optimize the use of the bandwidth of the first communication link 110a, data compression/decompression rules (which are three in number in this example, and referenced 120a, 120b and 120c) are used by the compressor and decompressor devices 100a, 100b. These rules form a compression/decompression context 120.

For example, the compression/decompression rules used are in SCHC format (SCHC being a context-based compression technique, see the above definition). Table 1 below gives an example of attributes of such a compression/decompression rule in the SCHC format (for example the rule referenced 120a).

TABLE 1

| Field | Target | Comparison | Compression/decompression |
|---|---|---|---|
| identifier | value | operator | function |
| C1 | 0x00 | Ignore | Do not send |
| C2 | 0x1230 | MSB(12) | LSB(4) |
| C3 | 0xABC0 | MSB(12) | LSB(4) |

More particularly, it may be seen that the compression/decompression rule 120a in question comprises a list of three field descriptions. Each field description corresponds to one row of table 1 above and defines a compression/decompression behavior for a determined field of the first data stream to be compressed/decompressed.

More particularly, it may be seen that the attributes of the rule 120a in question are, for a given field description (i.e. for a given row of table 1):
the identifier of the data field (i.e. a header field, in the case of a field description in SCHC format), among the data to be compressed/decompressed, to which, where appropriate, the compression/decompression function associated with the description in question (here the field C1 or C2 or C3 of the first column depending on the field description in question) will be applied;
the target value associated with the field identified by the field identifier of the first column;
the comparison operator that the rule 120a in question applies to compare the actual value of the data field identified by the identifier of the first column (i.e. the value of the field of the first data stream in question to be compressed or decompressed) and the target value for this field, i.e. the value such as listed in the second column of the table;
the compression/decompression function to be applied to the actual value of the data field identified by the identifier of the first column when the result delivered by the comparison operator of the second column is positive.

By way of example, we will consider the application of the rule the attributes of which are given in table 1 to compress the data packet composed of the three header fields C1, C2 and C3 and of their three current values 0x00, 0x1234 et 0xABCD, respectively, i.e. the data packet [0x00, 0x1234, 0xABCD].

It may be seen that:
the current value of the field C1 is unimportant, this value being ignored by the rule 120a in question. The corresponding compression function is always applied and the data bits of the field C1 are not sent in the present case;
the current value of the 12 MSB (for Most Significant Bits) of the field C2, i.e. 0x1230, corresponds to the expected target value. The corresponding compression function is therefore applied and only the 4 LSB (for Least Significant Bits) of the field C2, i.e. 0x4, are retained to be sent;
the current value of the 12 MSB (for Most Significant Bits) of the field C3, i.e. 0xABC0, corresponds to the expected target value. The corresponding compression function is therefore applied and only the 4 LSB (for Least Significant Bits) of the field C3, i.e. 0xD, are retained to be sent.

Thus, application of the rule 120a in question to the data packet [0x00, 0x1234, 0xABCD] delivers the compressed packet [0x4D] to be sent by the connected thing 130 to the application server 150 via the first communication link 110a on which the decompressor device 110b is found. Moreover, the connected thing 130 simultaneously sends the identifier of the rule 120a used by the compressor device 100a to compress the transmitted data.

Thus, the decompressor device 100b applies the same rule 120a to the compressed data that it receives and, in order to reconstruct the original data, carries out the inverse operations of those performed by the compressor device 100a, namely:
associating by default the value 0x00 with the field C1;
putting back the 12 MSB of 0x1230 concatenated with the LSB 0x4 received via the first communication link 110a so as to form the initial current value of the field C2, i.e. 0x1234;
putting back the 12 MSB of 0xABC0 concatenated with the LSB 0xD received via the first communication link 110a so as to form the initial current value of the field C3, i.e. 0xABCD.

Moreover, in the present first implementation, each of the compressor and decompressor devices 100a, 100b comprises a device 300 for learning a compression/decompression context. Other possible implementations are presented below.

Such a learning device 300, an example of a structure of which is described below with reference to FIG. 3, is able to obtain and process data of a second data stream transmitted between the compressor device 100a and the decompressor device 100b via a second communication link 110b.

For example, the second communication link 100b is a short-range radio communication link of the Wi-Fi®, Bluetooth®, IEEE 802.15.4 or ZigBee type or even a cellular (for example 2G/3G/4G, etc.) link, etc.

In certain embodiments (not shown) the learning device 300 is able to obtain and process data of a plurality of second data streams transmitted between the compressor device 100a and the decompressor device 100b via one or more second communication links 110b.

In variants, the second communication link 110b is a LPWAN link (for example a radio link according to one of the following standards: LoRa®, SIGFOX®, NB-IoT, EC-GPRS, LTE cat-M1, Weightless®, Ingenu/RPMA®, WI-SUN, etc.).

In other variants, the first 110a and second 110b communication links are two radio links based on two different modes of the same radiocommunication protocol (for example the IP mode of the NB-IoT standard, and the non-IP mode of the same standard (the non-IP mode of the NB-IoT standard also being known as DoNAS for “Data over NAS” or NIDD for “Non-IP Data Delivery”)).

Thus, the one or more learning devices 300 are able to implement the method for learning a compression/decompression context 120 described below with reference to FIG. 2.

With reference to FIG. 2, one embodiment of a method for learning a compression/decompression context 120 according to one embodiment of the described technique will now be described. This method is executed by each learning device 300 (i.e., in the present first implementation, by the learning device comprised in the compressor device 100a and by the learning device comprised in the decompressor device 100b).

In an analyzing step E200, the learning device 300 analyzes the second non-compressed data stream transmitted between the compressor device 100a and the decompressor device 100b via the second communication link 110b.

Such an analysis allows the learning device 300 to obtain the information required for the following step E210 of learning the compression/decompression context. This context is itself used for the subsequent compression and decompression of the first data stream to be transmitted via the first communication link 110a. The nature of the information in question is described below with reference to the learning step E210 and the corresponding substeps.

The learning step E210 comprises a selecting substep E210a and a modifying substep E210b.

In the selecting substep E210a, the learning device 300 selects at least one basic rule among a plurality of basic rules, depending on the second non-compressed data stream (and more precisely depending on the information obtained in the analyzing step E200).

In one embodiment, such basic rules are for example templates previously implemented in the learning device 300. One or more of these templates are thus selected then modified using the described technique in order to be able to be used to compress and decompress the first data stream exchanged over the first communication link 110a.

In another embodiment, such basic rules are current rules already used to compress and decompress the first data stream, but that it is desired to update using the described method.

According to one particular embodiment, one or more basic rules are selected on the basis of reference fields defined as such for a given rule 120a, 120b, 120c.

More particularly, each reference-field description (with the field-description notion such as introduced above with reference to table 1) of a rule in the SCHC format defines a compression/decompression behavior and a target value for a reference field.

Thus, the selecting substep E210a comprises, for each of the basic rules:

for each reference-field description defining a given target value for a given reference field, comparing E210a1 a current value of the given reference field in a packet of the second data stream, and the given target value; and

deciding E210a2 to select or not select the basic rule, depending on the comparison for each reference-field description.

Thus, each rule that the learning device 300 learns is based on one of the basic rules, which rule is identified (i.e. selected) simply and robustly via a comparison carried out between the target value and the current value of a reference field of the data, to which field this rule must be applied in order to carry out the compression or decompression.

According to certain embodiments, a reference field is a header field of a packet of the first data stream, transmitted via the first communication link 110a, and conveying static information.

More particularly, such a reference field is a header field conveying static information such as defined by a communication protocol used on the first communication link 110a. It is for example a question of the IP Internet protocol (e.g. Ipv4 or Ipv6), of the UDP protocol (UDP standing for User Datagram Protocol) or TCP protocol (TCP standing for Transmission Control Protocol), of the CoAP protocol (CoAP standing for Constrained Application Protocol), of the MQTT protocol (MQTT standing for MQ Telemetry Transport) or the WM-Bus protocol (WM-Bus standing for Wireless M-Bus), of the ZigBee protocol, etc.

Thus, one or more rules among the basic rules are identified (i.e. selected) via recognition of the value of a header field conveying a static parameter allowing the final recipient of the compressed data exchanged in the first data stream via the first communication link 110a to be identified (generally, any field containing an element allowing the final recipient in question to be identified may be considered to define a reference field). This final recipient is for example the decompressor 100b, a device into which the decompressor is integrated, or more particularly a final application 151 for which the data are intended after decompression by the decompressor 100b.

Thus, the described method allows a compression/decompression rule 120a, 120b, 120c specifically used for the exchange of compressed data with one particular recipient device to be learnt.

Moreover, one or more among the basic rules is or are identified (i.e. selected) robustly using a predefined criterion (i.e. using a criterion known before the establishment of the communication via the first communication link).

The one or more selected rules (i.e. selected among the basic rules) are modified in the modifying substep E210b in order to obtain the one or more compression/decompression rules 120a, 120b, 120c comprised in the compression/decompression context 120.

According to one embodiment, a rule selected among the basic rules is modified on the basis of adaptation fields defined as such for a given basic rule.

More particularly, each adaptation-field description (with the field-description notion such as introduced above with reference to table 1) of a rule in SCHC format defines a compression/decompression behavior and a target value for an adaptation field.

Therefore, the modification comprises, for each selected basic rule and for each adaptation-field description, modifying at least one attribute of the adaptation-field description, depending on the second data stream.

Thus, the one or more attributes of the rule 120a, 120b, 120c that it is desired to learn are updated flexibly via the information delivered in the second data stream by the second communication link 110b.

In one embodiment, for at least one attribute of the adaptation-field description (that it is desired to learn), this attribute is modified directly using a current value of the adaptation field in question in a packet of the second data stream. For example, this current value is employed as target value in the description of the adaptation field in question (see below the description of table 2).

In another embodiment, for at least one attribute of the adaptation-field description (that it is desired to learn), this attribute is modified depending on a current value of the adaptation field in question in a packet of the second data stream. For example, if the current value is employed as target value, then the comparison operator and/or the compression/decompression function automatically change values, i.e. switch to predetermined new values (see below the description of table 2). In this case, the predetermined new values of the attributes are defined beforehand in the learning device 300 implementing the modifying step E230b.

According to certain embodiments, an adaptation field is a header field of a packet of the first data stream, transmitted via the first communication link 110a, and conveying dynamic information.

More particularly, such an adaptation field is a header field conveying dynamic information such as defined by the communication protocol used on the first communication link 110a and described above with reference to the reference fields.

Thus, attributes (of the compression/decompression rules) associated with header fields conveying a dynamic parameter (generally, any field conveying such a dynamic parameter may be considered in order to define an adaptation field), i.e. a parameter that is not known before the establishment of the communication over the first communication link 110a, are learned.

Such an approach to learning allows the compression and decompression rules 120a, 120b, 120c to be adapted to changes in the dynamic parameterization of the communication between the compressor and decompressor devices 100a, 100b.

In one particular embodiment, by attributes of the description of an adaptation field, what is meant is:
a target value of the adaptation field;
a comparison operator enabling comparison between the target value and a current value of the adaptation field in a packet of the first data stream, with a view to delivering a decision to apply a compression or decompression function to the current value; and
the compression or decompression function in question.

Execution of the modifying substep E210b thus concludes the learning step E210 of the method for learning a compression/decompression context according to the described technique.

It may be seen that since the rules of the compression/decompression context 120 were learnt on the basis of information conveyed by the second non-compressed data stream (via the second communication link 110b), the bandwidth of the first communication link 110a remains dedicated to the exchange of useful data.

Moreover, the ability to learn the rules of the compression/decompression context 120 without affecting the available bandwidth of the first communication link 110a makes it possible to envision updating the context 120 in question more frequently. Thus, adaptation of the rules to the dynamic reparameterization of the exchange of data over the first communication link becomes envisionable.

Lastly, when the second communication link 110b has a broader bandwidth than that of the first communication link 110a, the length of time taken by the compressor and decompressor devices 100a, 100b to learn the compression context is decreased.

Moreover, in certain embodiments, no selecting step E210a is carried out. The modifying step E210b is then implemented by default for all the basic rules implemented in the learning device 300 and having a target value for an adaptation field a current value of which is received as useful datum in the data packet received via the second communication link 100b.

Such embodiments are advantageous for example when a single basic rule is implemented in the learning device 300. This may also be the case when the learning device 300 in question is implemented within a piece of equipment that is connected, by the first communication link 110a, only to a single recipient of the compressed data. Thus, the reference fields (identifying this single recipient) are identical for all the basic rules, thereby making redundant the implementation of the selecting step E210a in its embodiment based on a comparison of reference fields.

By way of example, table 2 below gives the field descriptions, with the corresponding attributes, of a basic compression/decompression rule, in SCHC format, before learning has been carried out by implementing the learning method described above.

The reference fields of this basic rule are assumed to be the fields C2 and C3 (identified as such by an asterisk in table 2), this information being associated with the basic rule itself and therefore known to the compressor and decompressor devices 100a, 100b.

TABLE 2

| Field | Target | Comparison | Compression/decompression |
|---|---|---|---|
| identifier | value | operator | function |
| C1 | | Ignore | Send |
| C2* | B | Equal | Do not send |
| C3* | C | Equal | Do not send |
| C4 | X | Equal | Do not send |

We will consider that the compressor and decompressor devices 100a, 100b receive, via the second non-compressed data stream conveyed by the second communication link 100b, a data packet the useful portion of which comprises information, for example [C1=A, C2=B, C3=C, C4=D], conveying current values associated with the fields C1 to C4. The fields C1 to C4 are header fields of the first data stream, to which field the compression and decompression must be applied, said compression and decompression being carried out by the compressor device 100a and the decompressor device 100b, respectively.

It may be seen that the current values of the fields C2 and C3 such as delivered by the data packet, i.e. “B” and “C” respectively in the present case, correspond to the target values of the reference fields of the basic rule the attributes of which are given in table 2.

Thus, during the implementation of the selecting step E210a of the learning method according to the described technique, the compressor and decompressor devices 100a, 100b select the basic rule of table 2 (said rule then being modified in order to obtain one of the rules of context).

In contrast, another basic rule, the reference fields of which do not have target values corresponding to the current values associated with the same fields in the data packet received via the second communication link 100b, is not selected (two different basic rules moreover being able to have different reference fields).

During the implementation of the modifying step E210b of the learning method according to the described technique, the compressor and decompressor devices 100a, 100b modify (update) the attributes of the basic rule selected beforehand and that are associated with the adaptation fields a current value of which is received as useful datum in the data packet received via the second communication link 100b. In the present case, it is a question of the attributes associated with the adaptation fields (also called learning fields) C1 and C4 of the basic rule of table 2 (the learning fields being different from the reference fields in the present case).

Thus, the target values associated with the fields C1 and C4 of the basic rule of table 2 (i.e. the rule selected) are updated to the values “A” and “D” if the value of the useful data of the data packet given as example above is employed.

Moreover, since the target value of the current field C1 is updated to a nonzero value, the value of the comparison operator associated with the field C1 is also updated with a predefined value for a nonzero value of the field C1, i.e. “Equal” in the present case. Likewise, the value of the compression/decompression function is updated with a predefined value “Do not send”.

In another embodiment, the new values of the comparison operator and of the compression/decompression function are delivered via the useful data of the data packet conveyed within the second non-compressed data stream (by the second communication link 110b).

Thus, after implementation of the learning method according to the described technique, the attributes of the basic rule of table 2 are updated. The result, forming one of the rules of the context 120, is given in table 3 below. Moreover, the identifier of the rule in question is not modified.

TABLE 3

| Field | Target | Comparison | Compression/decompression |
|---|---|---|---|
| identifier | value | operator | function |
| C1 | A | Equal | Do not send |
| C2* | B | Equal | Do not send |
| C3* | C | Equal | Do not send |
| C4 | D | Equal | Do not send |

Lastly, FIG. 3 shows an example of a structure of a learning device 300 allowing the method of FIG. 2 to be implemented. It comprises a random-access memory 303 and a processing unit 302 that is for example equipped with a processor and driven by a computer program stored in a read-only memory 301 (for example a hard disk). On initialization, the code instructions of the computer program are for example loaded into the random-access memory 303 before being executed by the processor of the processing unit 302.

In FIG. 3 only one particular way, among several possible ways, of implementing the algorithm detailed above with reference to FIG. 2 has been illustrated. Specifically, the described technique may be carried out either on a reprogrammable computational machine (a PC, a DSP or a microcontroller) executing a program containing a sequence of instructions, or on a dedicated computational machine (for example a set of logic gates such as an FPGA or ASIC, or any other hardware module).

In the case where the described technique is implemented by a reprogrammable computational machine, the corresponding program (i.e. the sequence of instructions) will optionally be stored in a removable storage medium (such as for example a floppy disk, a CD-ROM or a DVD-ROM), this storage medium being partially or completely readable by a computer or a processor.

In the first implementation described above with reference to FIGS. 1 to 3, each of the compressor and decompressor devices 100a, 100b comprises a device 300 for learning a compression/decompression context (and therefore they each carry out the learning method of FIG. 2). Thus, the overall implementation of such an approach to learning is simplified.

It will however be clear that other embodiments of the invention may be envisioned, without departing from the scope of the invention.

Thus, in a second implementation, only one of the compressor and decompressor devices 100a, 100b comprises a learning device 300 (and therefore carries out the learning method of FIG. 2). In this case, the compressor or decompressor device that does not learn receives the compression/decompression context resulting from the learning method carried out by the other.

In a third implementation, it is a third device (represented by a dashed box and referenced 100c in FIG. 1) that comprises a learning device 300 (represented by a dashed box in FIG. 1) and that therefore carries out the learning method of FIG. 2. In this case, the compressor device 100a and the decompressor device 100b each receive the compression/decompression context resulting from the learning method carried out by the third device 100c.

1. A method for learning a compression/decompression context comprising at least one compression/decompression rule intended to be used by a compressor device and a decompressor device (100b) to compress and decompress at least one first data stream transmitted via at least one first communication link, respectively, characterized in that at least one device, among the compressor device (100a), the decompressor device and a third device, carries out the following steps:
analyzing at least one second non-compressed data stream transmitted between the compressor device and the decompressor device via at least one second communication link; and
learning said at least one compression/decompression rule depending on said analysis;
in that said learning step comprises modifying at least one basic compression/decompression rule, in order to obtain said at least one compression/decompression rule comprised in said compression/decompression context,
in that said at least one basic compression/decompression rule comprises at least one adaptation-field description defining a compression/decompression behavior for an adaptation field of said at least one first data stream,
and in that said modification comprises, for each selected basic compression/decompression rule:
for each adaptation-field description, modifying at least one attribute of said adaptation-field description, depending on a current value of said adaptation field in a packet of said at least one second data stream.

2. The method of claim 1, wherein said at least one adaptation field is a header field of a packet of said at least one first data stream, said header field conveying dynamic information of a communication protocol.

3. The method of claim 1, wherein said at least one attribute of said at least one adaptation-field description belongs to the group comprising:
a target value of said adaptation field;
a comparison operator enabling comparison between said target value and a current value of said adaptation field in a packet of said at least one first data stream, with a view to delivering a decision to apply a compression or decompression function to said current value; and
said compression or decompression function.

4. The method of claim 1, wherein said learning step comprises selecting, depending on said at least one second non-compressed data stream, said at least one basic compression/decompression rule among a plurality of basic compression/decompression rules,
wherein each of the basic compression/decompression rules comprises at least one reference-field description defining a compression/decompression behavior and a target value for a reference field of said at least one first data stream,
and wherein said selection comprises, for each of the basic compression/decompression rules:
for each reference-field description defining a given target value for a given reference field, comparing a current value of said given reference field in a packet of said at least one second data stream, and said given target value; and
deciding to select or not select said basic compression/decompression rule depending on said comparison for each reference-field description.

5. The method of claim 4, wherein said at least one reference field is another header field of a packet of said at least one first data stream, said other header field conveying static information of a communication protocol.

6. The method of claim 5, wherein said at least one compression rule, comprised in said compression/decompression context, is in static context header compression (SCHC) format.

7. The method of claim 6, wherein said at least one first communication link is a link of a low-power wide-area network (LPWAN).

8. The method of claim 1, wherein said at least one second communication link is a link of a cellular wireless network.

9. The method of claim 1, wherein the decompressor device and the decompressor device each carry out the analyzing and learning steps.

10. The method of claim 1, wherein one of the compressor and decompressor devices carries out the analyzing and learning steps, and in that the other of the compressor and decompressor devices receives the compression/decompression context resulting from said analyzing and learning steps.

11. The method of claim 1, wherein the third device carries out the analyzing and learning steps, and in that the compressor device and the decompressor device each receive the compression/decompression context resulting from said analyzing and learning steps.

12. A computer-program product containing program-code instructions stored a non-transitory storage medium for implementing the method of claim 1, when said program-code instructions are executed by one or more processors.

13. A device for learning a compression/decompression context comprising at least one compression/decompression rule intended to be used by a compressor device and a decompressor device to compress and decompress at least one first data stream transmitted via at least one first communication link, respectively, comprises a reprogrammable computational machine or a dedicated computational machine able and configured to:
analyze at least one second non-compressed data stream transmitted between the compressor device and the decompressor device via at least one second communication link; and
learn said at least one compression/decompression rule depending on said analysis;
said learning comprising modifying at least one basic compression/decompression rule, in order to obtain said at least one compression/decompression rule comprised in said compression/decompression context,
said at least one basic compression/decompression rule comprising at least one adaptation-field description defining a compression/decompression behavior for an adaptation field of said at least one first data stream,
said modification comprising, for each selected basic compression/decompression rule:
for each adaptation-field description, modifying at least one attribute of said adaptation-field description, depending on a current value of said adaptation field in a packet of said at least one second data stream.
